(19) United States
(12) Patent Application Publication
(10) Pub. No.: US 2007/0074745 A1
(43) Pub. Date: Apr. 5, 2007

(54) Exhaust system for use in processing a substrate

(75) Inventors: Yoshio Kimura, Koshi-Shi (JP); Kouzou Kanagawa, Koshi-Shi (JP)

Correspondence Address: SMITH, GAMBRELL & RUSSELL, 1850 M STREET, N.W., SUITE 800, WASHINGTON, DC, 20036, US

(73) Assignee: Tokyo Electron Limited

(21) Appl. No.: 11/529,504

(22) Filed: Sep. 29, 2006

(30) Foreign Application Priority Data
Oct. 4, 2005 (JP) 2005-291046

(51) Int. Cl. B08B 6/00; B08B 7/00; H01L 21/00

(52) U.S. Cl. 134/42; 134/1.3; 438/800

(57) ABSTRACT

Disclosed is an exhaust system for discharging a fluid which is supplied into a hermetically closed container 54 for containing a semiconductor wafer W, a substrate to be supplied in the container 54 and subjected to a process. The exhaust system comprises an outer exhaust pipe 71 which is connected to the hermetically closed container via an exhaust connecting pipe 68 and has closed top and bottom ends, a downstream guide passage 201 which is provided in the outer exhaust pipe 71 and adapted to downwardly guide an exhaust fluid flowing through the outer exhaust pipe 71, and an upstream guide passage 202 which is adapted to upwardly guide the exhaust fluid having flowed through the downstream guide passage 201 as well as to cause foreign matter or the like in the exhaust fluid to be settled by gravity. The exhaust fluid having flowed through the upstream guide passage 202 is discharged from a discharging passage 203 to the outside.

### CROSS REFERENCE TO RELATED APPLICATIONS

This application is based upon the prior Japanese Patent Application No. 2005-291046 filed on Oct. 4, 2005, the entire contents of which are incorporated herein by reference.

1. Field of the Invention

The present invention relates to an exhaust system for use in processing a substrate, and in particular to an exhaust system for use in processing a substrate, for example, for heating substrates, such as semiconductor wafers or LCD glass substrates.

2. Background Art

In general, in manufacture of semiconductor devices, in order to form thin layers or electrode patterns of ITO (Indium Tin Oxide) on semiconductor wafers or LCD glass substrates (hereinafter referred to as wafer(s)), a photolithographic technique is utilized. In the photolithographic technique, a photoresist is first coated on each wafer or similar material, and the so-formed resist film is then exposed to light corresponding to a predetermined circuit pattern, and thereafter the exposed pattern is developed to form the circuit pattern in the resist.

In such a step of photolithography, various heating processes, such as a heating process after the resist coating (pre-baking), a heating process after the exposure (post-exposure baking), and a heating process after the developing process (post-baking) are provided.

Conventionally, among these heating processes, in the pre-baking process, a purge gas, such as air or nitrogen (N2), is supplied into a processing chamber containing wafers or similar material, and the fluid supplied into the processing chamber and used for the process is then exhausted to the outside through an exhaust pipe connected to the processing chamber. At this time, a small amount of foreign matter such as a sublimate (i.e., an acid-generating material contained in the photoresist, for example, PAG (Photo acid grain) of a low-molecular-weight resin constituting the resist) is produced from the resist film formed on the wafer surface upon heating. In particular, the amount of production of such a sublimate is greater in the case of a photoresist produced by using a non-ionic acid-generating material having a low boiling point. Accordingly, a trapping member, for example, a filter for trapping the foreign matter such as a sublimate is provided in each processing chamber to prevent the foreign matter in an exhaust fluid from being discharged to the outside (see, for example, Patent Document 1).

Cited Patent Document:

Patent Document 1: TOKUKAI No. 2003-347198, KOHO (claims, and FIGS. 5 and 6)

However, in the structure that the trapping member is provided in each processing chamber, it is quite difficult to increase the proportion of the space that the trapping member comprises in the processing chamber, thus limiting the trapping capability. Accordingly, in order to make the trapping member function more efficiently, the trapping member should be replaced at a proper time interval, and as such the process performed in each processing chamber must be stopped during the replacement of trapping members.

As a measure for solving the above problem, increase of trapping capacity of the trapping member can be considered. However, as the size of the trapping member is increased, the entire body of the processing system itself becomes larger. Additionally, in a processing system including a plurality of processing chambers, it becomes difficult to make the system be space-efficient.

### SUMMARY OF THE INVENTION

The present invention was made in light of the above, and therefore it is an object of this invention to provide an exhaust system which can ensure the trapping of foreign matter in an exhaust fluid and enable the increase of the trapping amount and miniaturization of the system.

The present invention is an exhaust system for use in processing a substrate, which is connected to a processing chamber for containing the substrate to be processed, and adapted to discharge a fluid from the processing chamber, comprising: an outer exhaust pipe connected to the processing chamber via an exhaust connecting pipe and having closed top and bottom ends; a downstream guide passage formed in the outer exhaust pipe and adapted to downwardly guide an exhaust fluid flowing through the outer exhaust pipe; an upstream guide passage formed in the outer exhaust pipe and adapted to upwardly guide the exhaust fluid having flowed through the downstream guide passage as well as to cause foreign matter or the like in the exhaust fluid to be settled by gravity; and a discharging passage formed in the outer exhaust pipe and adapted to downwardly guide the exhaust fluid having flowed through the upstream guide passage to the outside, wherein a discharging means is provided in the discharging passage.

According to the exhaust system constructed as described above, an exhaust fluid to be discharged from the processing chamber via the exhaust connecting pipe first flows through the downstream guide passage formed in the outer exhaust pipe, then flows through the upstream guide passage, during which foreign matter or the like in the exhaust fluid being settled by gravity, and thereafter the exhaust fluid from which the foreign matter or the like has been removed is discharged via the discharging passage to the outside.

The present invention is the exhaust system for use in processing a substrate, wherein the downstream guide passage is formed between the outer exhaust pipe and an intermediate exhaust pipe which is connected to the top end of the outer exhaust pipe and has an opening bottom end; and wherein the upstream guide passage is formed between the intermediate exhaust pipe and an inner exhaust pipe which is disposed in the intermediate exhaust pipe with a gap provided therebetween, has an opening top end, and extends through the bottom end of the outer exhaust pipe, and wherein the discharging passage is formed by the inner exhaust pipe.

According to the exhaust system constructed as described above, the downstream guide passage, the upstream guide passage and the discharging passage can be formed by arranging the intermediate exhaust pipe and the inner exhaust pipe in the outer exhaust pipe.

The present invention is the exhaust system for use in processing a substrate, wherein a plurality of exhaust connecting pipes each connected to a plurality of processing chambers are connected to the outer exhaust pipe.

According to the exhaust system constructed as described above, exhaust fluids having been discharged from a plurality of processing chambers can be discharged from one exhaust system.

The present invention is the exhaust system for use in processing a substrate, wherein a pressure detection means is provided in the outer exhaust pipe, for detecting pressure in the outer exhaust pipe so as to detect foreign matter or the like accumulated in the outer exhaust pipe.

According to the exhaust system constructed as described above, the pressure in the outer exhaust pipe can be measured by the pressure detection means, whereby a state of accumulation of foreign matter or the like accumulated in the bottom portion of the outer exhaust pipe can be detected.

The present invention is the exhaust system for use in processing a substrate, wherein a viewing window is provided near the bottom end of the outer exhaust pipe, for observing foreign matter or the like accumulated in the outer exhaust pipe to be observed with eyes.

According to the exhaust system constructed as described above, foreign matter or the like accumulated in the outer exhaust pipe can be checked visually through the viewing window.

The present invention is the exhaust system for use in processing a substrate, wherein the intermediate exhaust pipe is tapered to spread downwardly.

According to the exhaust system constructed as described above, the flow speed of the exhaust fluid flowing in the upstream guide passage can be decreased at a lower portion of the intermediate exhaust pipe.

The present invention is the exhaust system for use in processing a substrate, wherein among an inner wall face of the outer exhaust pipe, an inner wall face and an outer wall face of the intermediate exhaust pipe, and an outer wall face of the inner exhaust pipe, rough face portions for enhancing attachment of foreign matter in an exhaust fluid are formed at least in the inner wall face of the intermediate exhaust pipe and the outer wall face of the inner exhaust pipe According to the exhaust system constructed as described above, attachment of foreign matter or the like in the exhaust fluid to the rough faces can be facilitated.

The present invention is the exhaust system for use in processing a substrate, wherein the outer exhaust pipe is configured such that it can be divided into an upper half body to which the intermediate exhaust pipe is connected and a lower half body through which the inner exhaust pipe is inserted.

According to the exhaust system constructed as described above, the outer exhaust pipe can be divided into the upper half body and the lower half body, for washing.

The present invention is the exhaust system for use in processing a substrate, wherein an antistatic process is provided to the exhaust connecting pipe.

According to the exhaust system constructed as described above, attachment, to the exhaust pipe due to static electricity, of foreign matter or the like in the exhaust fluid flowing in the exhaust connecting pipe can be prevented.

Since the exhaust system of the present invention is constructed as stated above, the effects as described below can be obtained.
(1) According to the present invention, the exhaust fluid discharged from the processing chamber via the exhaust connecting pipe first flows though the downstream guide passage formed in the outer exhaust pipe, then flows through the upstream guide passage. During this operation, foreign matter or the like in the exhaust fluid is settled by gravity, and thereafter the exhaust fluid from which the foreign matter or the like has been removed is discharged via the discharging passage to the outside. Thus, trapping of the foreign matter in the exhaust fluid can be ensured, thereby increasing the trapping amount.
(2) According to the present invention, since the downstream guide passage, the upstream guide passage and the discharging passage can be formed by arranging the intermediate exhaust pipe and the inner exhaust pipe in the outer exhaust pipe, adding to the effect of (1), the system can be further miniaturized.
(3) According to the present invention, since exhaust fluids having been discharged from a plurality of processing chambers can be discharged from one exhaust system, adding to the effects of (1) and (2), the system can be further miniaturized as well as the exhaust amount of each exhaust pipe can be equalized.
(4) According to the present invention, since the pressure in the outer exhaust pipe can be measured by the pressure detection means, whereby a state of accumulation of foreign matter or the like accumulated in the bottom portion of the outer exhaust pipe can be detected, adding to the effects of (1) through (3), a state of foreign matter or the like which has been removed can be monitored from the outside.
(5) According to the present invention, since foreign matter or the like accumulated in the outer exhaust pipe can be checked visually through the viewing window, adding to the effects of (1) through (4), the foreign matter or the like which has been removed can be further checked visually.
(6) According to the present invention, since the flow speed of the exhaust fluid flowing in the upstream guide passage can be decreased at a lower portion of the intermediate exhaust pipe, adding to the effects of (1) through (5), the settling of foreign matter by gravity of foreign matter in the exhaust fluid can be enhanced, thereby further ensuring the removal of foreign matter or the like.
(7) According to the present invention, since attachment of foreign matter or the like in the exhaust fluid to the rough faces can be facilitated, adding to the effects of (1) through (6), the removal of foreign matter or the like in the exhaust fluid can be further ensured.
(8) According to the present invention, since the outer exhaust pipe can be divided into the upper half body and the lower half body, for washing, a washing work for removing accumulated foreign matter or the like can be facilitated. Due to such washing, the system can be repeatedly used, thus enhancing the service life of the system.
(9) According to the present invention, since foreign matter or the like in the exhaust fluid flowing in the exhaust connecting pipe can be prevented from attaching to the exhaust connecting pipe due to static electricity, adding to the effects of (1) through
(8), clogging in the exhaust connecting pipe due to the foreign matter or the like in the exhaust fluid can be prevented from occurring.

### BRIEF DESCRIPTION OF THE DRAWINGS

FIG. 1 is a schematic plan view showing one example of a resist liquid coating and developing system to which a substrate processing apparatus comprising an exhaust system according to the present invention is applied.

FIG. 2 is a schematic front view of the resist liquid coating and developing system.

FIG. 3 is a schematic back view of the resist liquid coating and developing system.

FIG. 4 is a schematic cross section showing a state of use of a first embodiment of an exhaust system according to the present invention.

FIG. 5 is a perspective view showing the exhaust system and a heating system.

FIG. 6 is an enlarged cross section showing a key portion of the exhaust system.

FIG. 7 is a perspective view showing a divided state of an outer exhaust pipe in the present invention.

FIG. 8 is a cross-sectional perspective view showing a key portion of a second embodiment of the exhaust system according to the present invention.

FIG. 9 is a schematic cross section showing a third embodiment of the exhaust system according to the present invention.

### DETAILED DESCRIPTION OF THE INVENTION

Hereinafter, several embodiments each considered as one of the best modes of this invention will be described with reference to the appending drawings. Now, a case where an exhaust system according to the present invention is applied to a heating system employed in a resist liquid coating and developing system for semiconductor wafers will be described.

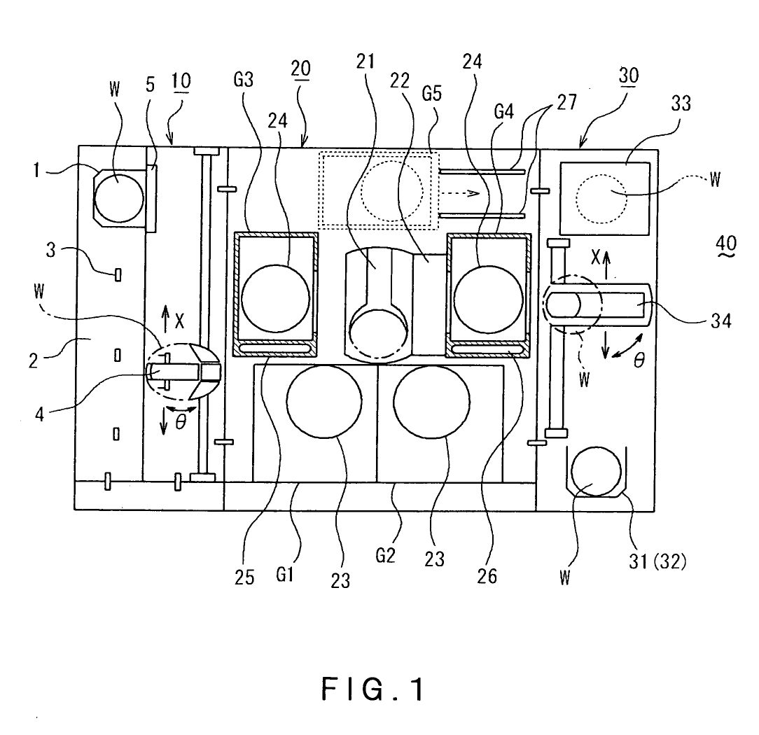

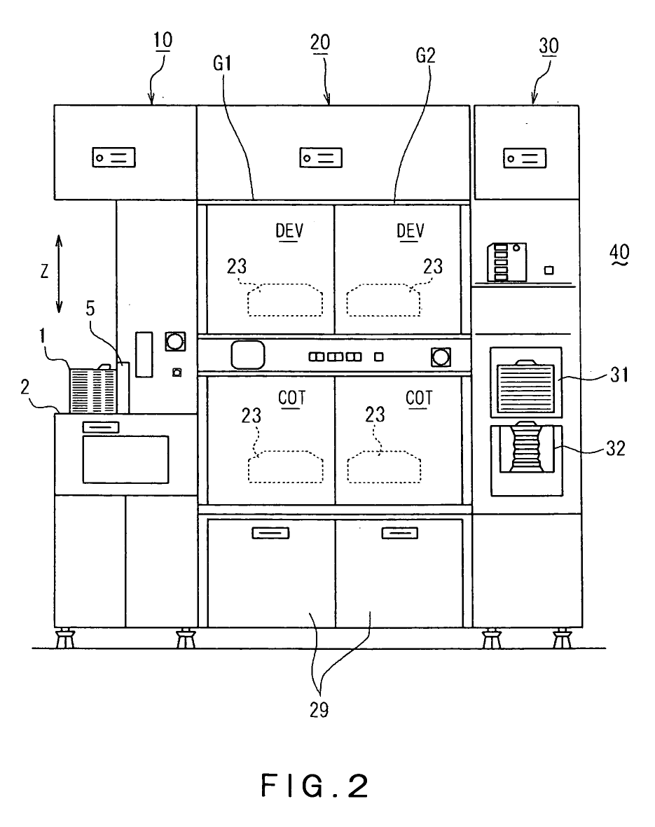

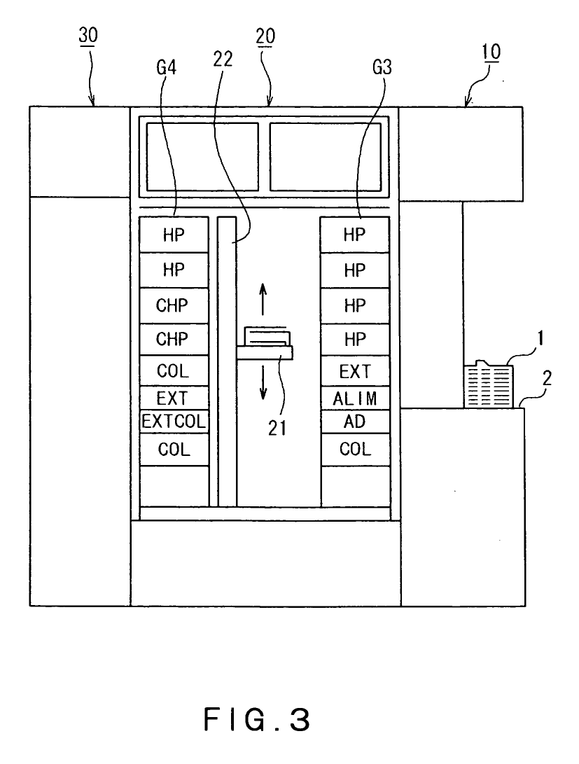

FIG. 1 is a schematic plan view showing one embodiment of the resist liquid coating and developing system, FIG. 2 is a schematic front view, and FIG. 3 is a schematic back view, of the system.

The resist liquid coating and developing system comprises a cassette station 10 (carrying portion) for carrying a plurality, for example, twenty-five pieces, of semiconductor wafers W (hereinafter, referred to wafer(s) W) into or out of the system by using a wafer cassette 1, or for carrying wafers W into or out of the wafer cassette 1; a processing station 20 including a processing system composed of various sheet-fed type processing units each adapted to provide a predetermined process to a wafer, one at a time, in a coating and developing step and arranged at a predetermined position in a multi-stage form; and an interface 30 for transferring each wafer W between the processing station 20 and an exposure system (not shown) disposed in the proximity of the processing station 20.

The cassette station 10, as shown in FIG. 1, includes a cassette placing table 2. At the respective position of projections 3 on the cassette placing table 2, a plurality, for example up to four, of covered wafer cassettes 1 are arranged in a line along the horizontal X direction with their wafer entrances facing the processing station 20. A cover opening and closing system 5 is arranged corresponding to each wafer cassette 1. In addition, wafer carrying tweezers 4 are provided to selectively carry each wafer cassette 1, such that the tweezers 4 can be moved both in the cassette arranging direction (X direction) and in the wafer arranging direction (Z direction) of the wafers W contained along the vertical direction in the wafer cassette 1. The wafer carrying tweezers 4 are configured to rotate in the θ direction as well as to move to an alignment unit (ALIM) and an extension unit (EXT) included in multi-stage units of a third group G3 on the side of processing station 20, which will be described below.

The processing station 20, as shown in FIG. 1, has a main wafer carrying mechanism 21 of a vertically carrying type to be driven in the vertical direction by a transfer mechanism 22. Around the main wafer carrying mechanism 21, all of processing units are arranged in a multi-stage form in one or plural groups. This example is configured to have five groups, i.e., G1, G2, G3, G4 and G5 each being in a multi-stage form, wherein multi-stage units of first and second groups G1, G2 are arranged on the front side of the system, multi-stage units of third group G3 are arranged in the proximity of the cassette station 10, multi-stage units of fourth group G4 are arranged in the proximity of the interface 30, and multi-stage units of fifth group G5 are arranged on the back side of the system.

In this case, as shown in FIG. 2, in the first group G1, a resist coating unit (COT) adapted to place a wafer W on a spin chuck (not shown) and provide a predetermined process to the wafer and a developing unit (DEV) adapted to bring the wafer W to face a developing liquid supply means (not shown) in a cup (or container) 23 and develop a resist pattern are vertically superimposed on each other, successively from below, into a two-stage form. In the second group G2, the resist coating unit (COT) and the developing unit (DEV) are vertically superimposed on each other, successively from below, into a two-stage form. The reason for disposing the resist coating unit (COT) on the lower stage is that drainage of the resist liquid is troublesome not only in the operation but also in the maintenance. However, if desired, the resist coating unit (COT) may disposed at the upper stage.

As shown in FIG. 3, in the third group G3, an oven type processing unit, for example, a cleaning unit for cleaning the wafer (COL), which is adapted to place a wafer W on a wafer placing table 24 and provide a predetermined process to the wafer, an adhesion unit (AD) for rendering the wafer hydrophobic, an alignment unit (ALIM) which performs alignment of the wafer W, an extension unit (EXT) for carrying-in and carrying-out of the wafer W, and four hot plate units (HP) each adapted to bake the wafer W and employing a heating system comprising an exhaust system according to the present invention, are superimposed on one another, successively from below, into, for example, an eight-stage form. Similarly, in the fourth group G4, an oven type processing unit, for example, the cleaning unit (COL), an extension cleaning unit (EXTCOL), the extension unit (EXT), the cleaning unit (COL), two chilling hot plate units (CH) each having a cooling function and employing a heating system comprising an exhaust system according to the present invention, and two hot plate units (HP) each employing a heating system comprising an exhaust system according to the present invention, are superimposed on one another, successively from below, into, for example, an eight-stage form.

By arranging the cooling unit (COL) and extension cleaning unit (EXTCOL), of a low processing temperature, so as to be disposed at lower stages, with the hot plate units (HP), chilling hot plate units (CH) and adhesion unit (AD), of a high processing temperature, so as to be disposed at upper stages, thermal mutual interference between these units can be reduced. Of course, random multi-stage arrangement may also be provided.

As shown in FIG. 1, in the processing station 20, ducts 25, 26 are provided respectively in side walls of the multi-stage units (oven type processing units) of the third and fourth groups G3, G4 contiguous to the multi-stage units (spinner type processing units) of the first and second groups G1, G2, such that they extend through these units in the vertical direction. In addition, these ducts 25, 26 are configured such that downflow clean air or specially temperature-controlled air is directed therein, respectively. Due to such a duct configuration, the heat generated by the oven type processing units of the third and fourth groups G3, G4 is shut off so that it can not be conducted to the spinner type processing units of the first and second groups G1, G2.

In the processing system, multi-stage units of the fifth group G5 may be arranged as shown by dotted lines in FIG. 1 on the back side of the main wafer carrying mechanism 21. The multi-stage units of the fifth group G5 are configured to move laterally, when viewed from the main wafer carrying mechanism 21, along guide rails 27. Accordingly, even in the case where the multi-stage units of the fifth group G5 are provided, a proper space can be secured by slide movement of these units, as such facilitating to provide maintenance work to the main wafer carrying mechanism 21 from behind.

As compared to the processing station 20, the interface 30 is of the same size in the direction from front to back, while having a smaller size in the width direction. The interface 30 includes a movable pickup cassette 31 arranged in a two-stage form at a front portion, a fixed buffer cassette 32, a peripheral exposure system 33 which is a means adapted to provide exposure to the periphery of wafer W as well as to its identification mark, and a carrying arm 34 of a wafer, which is a carrying means disposed at a central portion. The carrying arm 34 is configured to move both in the X and Z directions so as to carry a wafer to both the cassette 31, 32 as well as to the peripheral exposure system 33. The carrying arm 34 is configured to rotate in the θ direction, such that it can carry a wafer to the extension unit (EXT) in the multi-stage units of the fourth group G4 on the side of processing station 20 as well as to a wafer transfer table (not shown) of the adjacent exposure system.

While the processing system configured as described above is installed in a clean room 40, cleanliness of each portion in the system is further enhanced by employing an efficient vertical laminar flow type structure.

In the resist liquid coating and developing system configured as described above, first, in the cassette station 10, a cover of a predetermined wafer cassette 1 is opened by actuation of the cover opening and closing system 5. Then, the wafer carrying tweezers 4 are driven to access the cassette 1 containing unprocessed wafers W on the cassette placing table 2 to take out one sheet of wafer W from the cassette 1. Once taking out the wafer W from the cassette 1, the wafer carrying tweezers 4 moves to the alignment unit (ALIM) disposed in the multi-stage units of the third group G3 on the side of the processing station 20, then transfers the wafer W onto the wafer placing table 24 in the unit (ALIM). The wafer W is then subjected to necessary alignment and centering, on the wafer placing table 24. Thereafter, the main wafer carrying mechanism 21 is driven to access the alignment unit (ALIM) from the opposite side and receives the wafer W from the wafer placing table 24.

In the processing station 20, the main wafer carrying mechanism 21 carries first the wafer W into the adhesion unit (AD) of the multi-stage units of the third group G3. In the adhesion unit (AD), the wafer undergoes a hydrophobicity rendering process. Once the hydrophobicity rendering process is ended, the main wafer carrying mechanism 21 carries the wafer W out of the adhesion unit (AD), and then carries it into the cleaning unit (COL) of the multi-stage units of the third group G3 or fourth group G4. In this cleaning unit (COL), the wafer W is cooled to a preset temperature, for example, 23° C. before subjected to a resist coating process. Once this cooling process is ended, the main wafer carrying mechanism 21 carries the wafer W out of the cooling unit (COL), then carries it into the resist coating unit (COT) of the multi-stage units of the first group G1 or second group G2. In the resist coating unit (COT), the wafer W is coated with a resist to give an even film thickness on the wafer surface by employing a spin coating method.

After completion of the resist coating process, the main wafer carrying mechanism 21 carries the wafer W out of the resist coating unit (COT), then carries it into the hot plate unit (HP). In the hot plate unit (HP), the wafer is placed on a placing table, and then subjected to a pre-baking for a predetermined period of time at a predetermined temperature, for example, 100° C. Thus, the remaining solvent can be evaporated and removed from the coated film on the wafer W. Once the pre-baking is finished, the main wafer carrying mechanism 21 carries the wafer W out of the hot plate unit (HP), and then carries it into the extension cleaning unit (EXTCOL) of the multi-stage units of the fourth group G4. In this unit (EXTCOL), the wafer W is cooled to a temperature, for example, 24° C., which is suitable for a next step, i.e., a peripheral exposure process in the peripheral exposure system 33. After the cooling, the main wafer carrying mechanism 21 carries the wafer W into an immediately upper extension unit (EXT) and places the wafer W on a placing table (not shown) in the unit (EXT). When the wafer W is placed on the placing table of the extension unit (EXT), the carrying arm 34 of the interface 30 is driven to access the wafer W from the opposite side and receives it thereon. Then, the carrying arm 34 carries the wafer W to the peripheral exposure system 33 in the interface 30. In the peripheral exposure system 33, an extra-resist film portion of the periphery on the surface of wafer W is irradiated with light to provide peripheral exposure.

After the peripheral exposure process is ended, the carrying arm 34 carries the wafer W out of a housing of the peripheral exposure system 33, then transfers it onto a wafer receiving table (not shown) on the side of the adjacent exposure system. In this case, the wafer W may be temporarily stored in the buffer cassette 32 before transferred to the exposure system.

When full-face exposure is finished in the exposure system and the wafer W is placed back on the wafer receiving table on the side of the exposure system, the carrying arm 34 of the interface 30 is driven to access the wafer receiving table and receives it thereon, carries it into the extension unit (EXT) of the multi-stage units of the fourth group G4 on the side of the processing station 20, and places the wafer W on the receiving table in the extension unit (EXT). In this case, the wafer W may be temporarily stored in the buffer cassette 32 in the interface 30 before transferred to the processing station 20.

The wafer W placed on the wafer receiving table is then carried by the main wafer carrying mechanism 21 to the chilling hot plate unit (CHP). In order to prevent occurrence of a fringe or induce an acid-catalytic reaction in a chemically-amplified type resist (CAR), a post-exposure baking process is provided for a predetermined period of time at a temperature of, for example, 120° C.

Thereafter, the wafer W is carried into the developing unit (DEV) of the multi-stage units of the first group G1 or second group G2. In this developing unit (DEV), a developing liquid is supplied evenly to the resist on the surface of wafer W so as to provide a developing process. Due to this developing process, the resist film formed on the surface of wafer W is developed into a predetermined circuit pattern, an extra-resist film in the periphery of the wafer W is removed, and a resist film attached onto an alignment mark M formed (or provided) on the surface of wafer W is also removed. In this way, upon the finish of the developing process, a rinsing liquid is poured on the surface of wafer W so as to wash away the developing liquid.

Upon finishing the developing process, the main wafer carrying mechanism 21 carries the wafer W out of the developing unit (DEV), and then carries it into the hot plate unit (HP) of the multi-stage units of the third group G3 or fourth group G4. In this unit (HP), the wafer W is subjected to a post-baking process at, for example, 100° C. for a predetermined time. Consequently, the resist which has been swelled in the developing process is hardened, thereby enhancing its chemical resistance.

When the post-baking is ended, the main wafer carrying mechanism 21 carries the wafer W out of the hot plate unit (HP), and then carries it into the cleaning unit (COL). In this unit, the temperature of the wafer W is returned to an ordinary temperature. Thereafter, the main wafer carrying mechanism 21 carries the wafer W into the extension unit (EXT) of the third group G3. Once the wafer W is placed on a placing table (not shown) of the extension unit (EXT), the wafer carrying tweezers 4 provided in the cassette station 10 is driven to access the wafer W from the opposite side to receive it. Then, the wafer carrying tweezers 4 place the wafer W in a predetermined wafer containing groove of a wafer cassette 1, for containing processed wafers, on the cassette placing table. Once all of processed wafers W are contained in the wafer cassette 1, the cover opening and closing system 5 is actuated to close the cover and the whole process is completed.

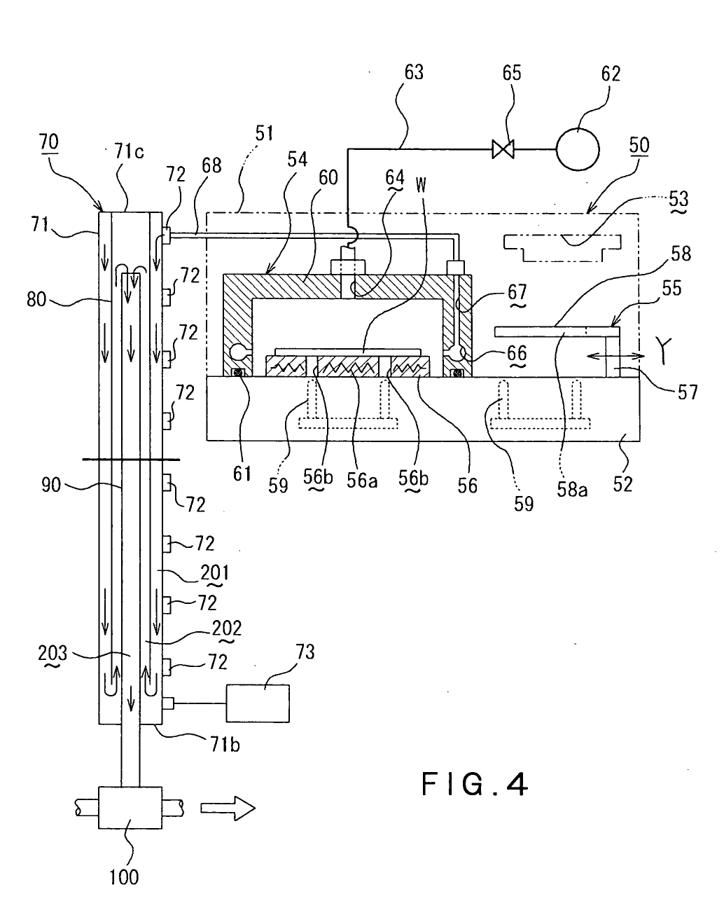

Next, an exhaust system in the heating process according to the present invention, which constitutes the hot plate unit (HP) and chilling hot plate unit (CHP), will be described with reference to FIGS. 4 through 9. In this section, a case where an exhaust system according to the present invention is applied to a heating system for pre-baking a wafer W which was coated with a resist is described.

### First Embodiment

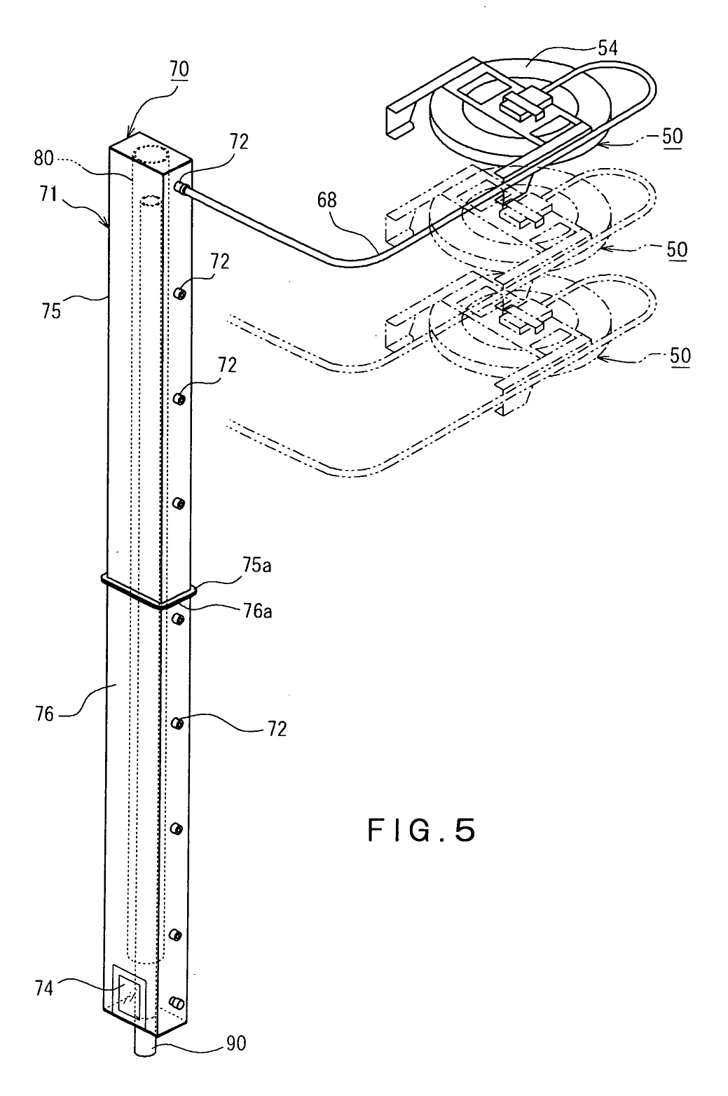

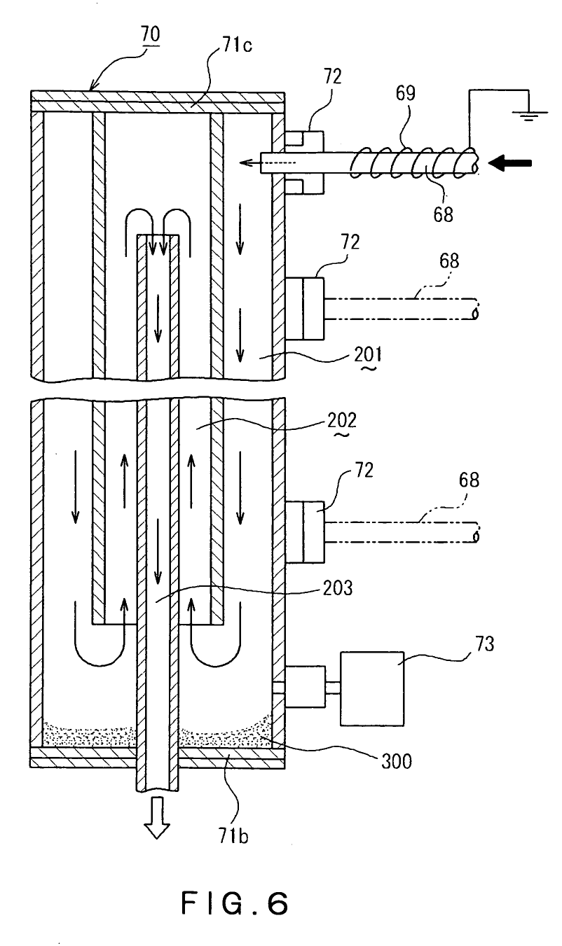

FIG. 4 is a cross section showing a state of use of a first embodiment of an exhaust system according to the present invention, FIG. 5 is a perspective view showing the exhaust system and a heating system, and FIG. 6 is an enlarged cross section showing a key portion of the exhaust system.

A heating system 50 includes a housing 51 placed around its outer periphery and formed of aluminum, for example. In the interior of the housing 51, a stage 52 is provided. In left and right side walls of the housing 51, an opening 53 is formed at portions which hold the stage 52 therebetween, the opening 53 being adapted to carry in or carry out a wafer W from the front side. At back ends, a cooling fluid passage (not shown) is formed vertically extending through the housing 51. The opening 53 is configured to selectively open and close by using a shutter (not shown), and the cooling fluid passage is adapted to cool a surrounding atmosphere of a hermetically sealed container 54 which is a processing chamber and will be described below. For example, the cooling fluid passage is configured to receive temperature-controlled cooling water supplied from a storing portion (not shown).

Above the stage 52, a cooling arm 55 is provided at a front end portion, while a heating plate 56 is provided at a back end portion. The cooling arm 55 serves to transfer a wafer W between the main wafer carrying mechanism 21, which enters the housing 51 through the opening 53, and the heating plate 56 as well as to cool a heated wafer W (roughly remove heat of wafer W) while carrying the wafer W. Accordingly, as shown in FIG. 4, a leg 57 is configured to move front and back in the Y direction along a guide means (not shown) provided on the stage 52, such that a wafer supporting plate 58 which is held horizontally at a top end of the leg 57 can be moved from a side position of the opening 53 to a position above the heating plate 56. In the wafer supporting plate 58, a cooling passage (not shown) is provided, for example, on its rear face side to flow temperature-controlled water therein.

Three supporting pins 59 which can be optionally project and retract from the upper face of the stage 52 are provided, at a transfer position of wafer W between the main wafer carrying mechanism 21 and the wafer supporting plate 58, and at a transfer position of wafer W between the heating plate 56 and the wafer supporting plate 58, in the stage 52, respectively. In addition, slits 58a are formed in the wafer supporting plate 58 such that the supporting pins 59 can extend upward through these slits 58a when they are driven to rise, thereby lifting up the wafer W. A heater 56a is embedded in the heating plate 56, and through-holes 56b are provided at appropriate positions of the heating plate 56, through which the supporting pins 59 can extend upward when they are actuated to rise.

A cover 60 is provided above the heating plate 56, which is moved vertically due to actuation of a lifting mechanism (not shown). When the cover 60 is in its lowered position (or during the heating process), for example, as shown in FIG. 4, the cover 60 surrounds the outer periphery of the heating plate 56 as well as hermetically connects with the stage 52 via an O-ring 61, a sealing member, thus defining a hermetically sealed container 54 for making the atmosphere in which a wafer W is placed be hermetically sealed. The heating plate 56 is formed of, for example, aluminum nitride (AIN), and configured such that a wafer W is placed horizontally on its surface.

To a ceiling of the cover 60, an air supply line 63 one end of which is connected to an air supply means 62, is connected at the other end. The air supply line 63 is adapted to supply air into the hermetic container 54 via a supply port 64 formed, for example, centrally, in the ceiling, by opening an opening and closing valve 65 provided in the middle of the air supply line 63. In a side wall of the cover 60, a plurality of peripheral channels are provided, for example, over the whole circumference, at a position facing a side face of a wafer W when the cover is in its lowered position. Each peripheral channel 66 is adapted to perform exhaustion of the inner atmosphere of the hermetic container 54, and is connected with an exhaust system 70 according to the present invention through a fluid passage 67 formed in the side wall of the cover 60 and an exhaust connecting pipe 68 formed from, for example, a fluororesin tube and connected to the fluid passage 67 at its one end.

The exhaust system 70, as shown in FIGS. 4 and 5, comprises a rectangular outer exhaust pipe (an exhaust pipe having a rectangular cross section) 71 which is formed from, for example, stainless steel and is closed at its both top and bottom ends, a cylindrical intermediate exhaust pipe (an exhaust pipe having a circular cross section) 80 which is formed from, for example, stainless steel, disposed in the outer exhaust pipe 71, connected with an 71c of the outer exhaust pipe 71, and has an opening bottom end, a cylindrical inner exhaust pipe 90 which is formed from, for example, stainless steel, disposed in the intermediate exhaust pipe 80 with a space provided therebetween, opened at its top end, and extends through the bottom end 71b of the outer exhaust pipe 71, and an exhaust means, for example, an ejector 100, which is provided to the inner exhaust pipe 90. The outer exhaust pipe 71 and the intermediate exhaust pipe 80 form a downstream guide passage 201 for downwardly guiding an exhaust fluid, and the intermediate exhaust pipe 80 and the inner exhaust pipe 90 form an upstream guide passage 202 adapted for upwardly guiding the exhaust fluid as well as for causing foreign matter in the exhaust fluid to be settled by gravity. In addition, the inner exhaust pipe 90 forms a discharging passage 203. In this case, the outer exhaust pipe 71 is formed to have a rectangular transverse cross section, while each of the intermediate exhaust pipe 80 and the inner exhaust pipe 90 is formed to have a circular transverse cross section. However, the shapes of the outer exhaust pipe 71, intermediate exhaust pipe 80 and inner exhaust pipe 90 are not limited to them, but may be of any given tubular shape with a proper cross section. For example, all of them may be formed into rectangular tube shapes or circular tube shapes.

For example, at one side wall of the outer exhaust pipe 71, a plurality of connecting portions 72 for the exhaust pipe 68 are provided with an appropriate interval therebetween along the longitudinal direction of the outer exhaust pipe 71. When connected to one of the connecting portions 72, as shown in FIG. 6, the exhaust connecting pipe 68 is connected to the outer exhaust pipe 71 such that the inner diameter of the exhaust connecting pipe 68 is not changed. Thus, an exhaust fluid flowing in the exhaust connecting pipe 68 can flow into the downstream guide passage 201 in the outer exhaust pipe 71 without causing an eddy current. As described above, by providing the plurality of connecting portions 72 for the exhaust connecting pipe 68 along the longitudinal direction of the outer exhaust pipe 71, a plurality of heating systems 50 can be connected to the outer exhaust pipe 71 vertically in a multi-stage form. This is suitable as an exhaust portion for a resist coating and developing system including a plurality of heating systems 50. The other end of the exhaust connecting pipe 68 is connected with the hermetic container (processing chamber) 54.

An antistatic means is provided to the exhaust connecting pipe 68. For example, as shown in FIG. 6, the antistatic means may be provided to the exhaust connecting pipe 68 by grounding electrically conductive coils 69 wound around the outer periphery of the exhaust connecting pipe 68. In place of using the electrically conductive coils 69, such grounding may be achieved by providing, for example, carbon wires along the longitudinal direction of the exhaust connecting pipe 68. Otherwise, the exhaust connecting pipe 68 itself may be formed of an electrically conductive material to provide a grounding means. In this way, by providing an antistatic means to the exhaust connecting pipe 68, attachment to the inner wall of the exhaust connecting pipe 68 of foreign matter, such as a sublimate, in an exhaust fluid flowing in the exhaust connecting pipe 68 can be prevented.

On one side of the lower portion of the outer exhaust pipe 71, a manometer 73 as a pressure detection means for detecting the pressure in the outer exhaust pipe 71 is provided such that foreign matter 300 accumulated on the bottom end 71b in the outer exhaust pipe 71 can be detected (see FIGS. 4 and 6).

Furthermore, in a part of the wall near the bottom end 71b of the outer exhaust pipe 71, a viewing window 74 is provided to observe the foreign matter 300 or the like accumulated on the bottom end 71b of the outer exhaust pipe 71 with eyes (see FIG. 5).

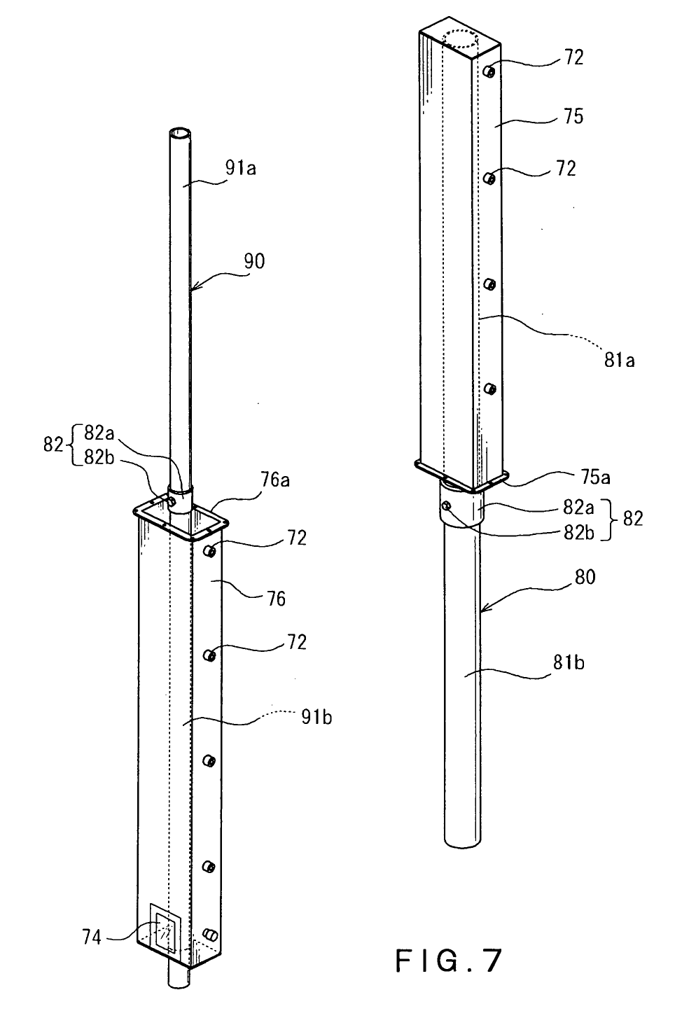

The outer exhaust pipe 71 is formed such that it can be divided into an upper half body 75 to which the intermediate exhaust pipe 80 is connected and a lower half body 76 through which the inner exhaust pipe 90 is inserted. The upper half body 75 and the lower half body 76 are connected with each other by fastening securing bolts (not shown) through a gasket (not shown) disposed between an outwardly extending flange 75a provided at a bottom end of the upper half body 75 and an outwardly extending flange 76a provided at a top end of the lower half body 76. Due to such a configuration, the downstream guide passage 201, upstream guide passage 202 and discharging passage 203 can be formed. While either of the intermediate exhaust pipe 80 and the inner exhaust pipe 90 can be formed in an integral tubular fashion, as shown in FIG. 7 and similar to the outer exhaust pipe 71, they may be formed to have upper half bodies 81a, 91a and lower half bodies 81b, 91b, respectively. In this case each bottom end of the upper half bodies 81a, 91a and each top end of the lower half bodies 81b, 91b may be connected with each other by using a connecting member 82 composed of a connecting collar 82a and a connecting screw 82b.

In the exhaust system 70 constructed as described above, when driving the ejector 100 as an exhaust means, a uniformly negative pressure can be provided in the outer exhaust pipe 71 through the discharging passage 203 of the inner exhaust pipe 90, an exhaust fluid flowing in the exhaust connecting pipe 68 then goes down through the downstream guide passage 201 as shown in FIGS. 4 and 6, enters the bottom opening of the intermediate exhaust pipe 80 then rises up through the upstream guide passage 202. At this time, foreign matter, such as a sublimate, contained in the exhaust fluid is settled by gravity and falls down on the bottom end 71b of the outer exhaust pipe 71, or otherwise attached to an inner wall face 80a of the intermediate exhaust pipe 80 and an outer wall face 90b of the inner exhaust pipe 90. Thereafter, the exhaust fluid which has risen up through the upstream guide passage 202 enters a top end opening of the inner exhaust pipe 90 and is then exhausted to the outside via the discharging passage 203. It can be appreciated that the settling by gravity of the foreign matter such as a sublimate can be further ensured by increasing the length of the upstream guide passage 202 and/or enlarging its cross section. By forming the outer exhaust pipe 71, intermediate exhaust pipe 80 and inner exhaust pipe 90, from stainless steel, as described above, the exhaust fluid having been heated in the hermetic container 54 (processing chamber) can be cooled when it flows through the exhaust system 70 before discharged to the outside.

When foreign matter is accumulated in the bottom end 71b of the outer exhaust pipe 71 and/or attached to the upstream guide passage 202 and the downstream guide passage 201, the pressure in the outer exhaust pipe 71 is changed (into a higher pressure). Therefore, it can be possible to know whether the exhausting ability of the exhaust system 70 is appropriate by detecting the pressure change using the manometer 73. Further, the extent of accumulation of the foreign matter can be checked by observing it with eyes through the viewing window 74. Otherwise, an electrical capacitance sensor may be provided to detect the height of the accumulated foreign matter. In this way, if the exhausting ability of the exhaust system 70 reaches a limit, the exhausting operation is stopped, and the outer exhaust pipe 71 is then divided into the upper half body 75 and lower half body 76, followed by dipping and washing them in a washing tank. Thereafter, the upper half body 75 and lower half body 76 are connected again with each other so as to restart the exhausting work.

### Second Embodiment

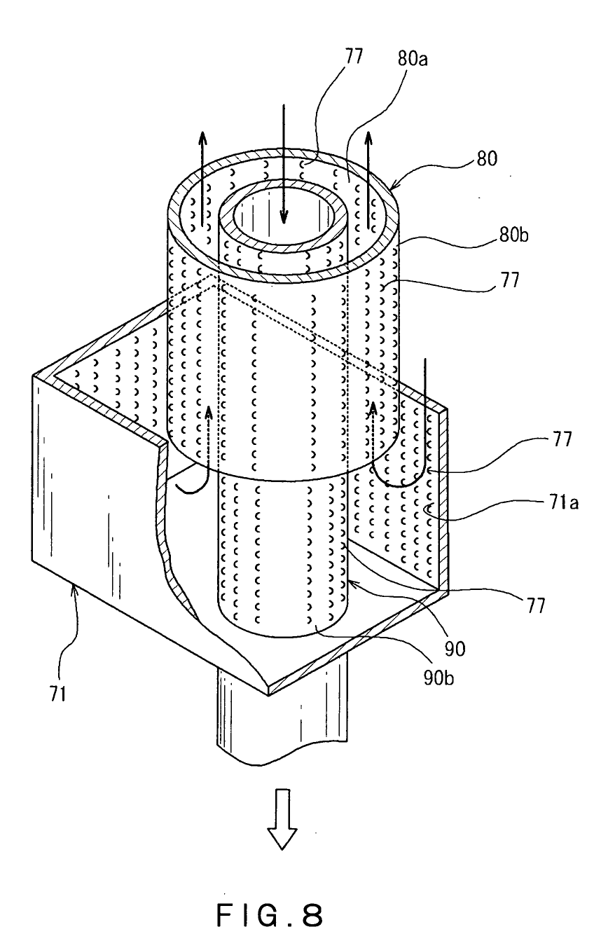

FIG. 8 is a cross-sectional perspective view showing a key portion of a second embodiment of the exhaust system according to the present invention.

The second embodiment is one example in which foreign matter such as a sublimate contained in an exhaust fluid can be removed more securely. As shown in FIG. 8, rough face portions 77 for enhancing attachment of foreign matter in an exhaust fluid are formed in an inner wall face 71a of the outer exhaust pipe 71, inner wall face 80a and outer wall face 80b of the intermediate exhaust pipe 80, and outer wall face 90b of the inner exhaust pipe 90.

In such a manner, by forming the rough face portions 77 for enhancing attachment of foreign matter in an exhaust fluid at least in the inner wall face 80a of the intermediate exhaust pipe 80 and the outer wall face 90b of the inner exhaust pipe 90, attachment of the foreign matter to the inner wall face 80a of the intermediate exhaust pipe 80 and the outer wall face 90b of the inner exhaust pipe 90, which constitute together the upstream guide passage 202, can be enhanced. In addition, the flow speed of the exhaust fluid flowing the upstream guide passage 202 can be decreased, and the settling by gravity of the foreign matter can be enhanced. In addition, by forming the rough face portions 77 in the inner wall face 71a of the outer exhaust pipe 71 and the outer wall face 80b of the intermediate exhaust pipe 80, which constitute together the downstream guide passage 20, attachment of the foreign matter in an exhaust fluid flowing in the downstream guide passage 201 can also be enhanced.

It is noted that the other portions in the second embodiment than described above are the same as those in the first embodiment. Accordingly, the description of such portions is omitted here.

### Third Embodiment

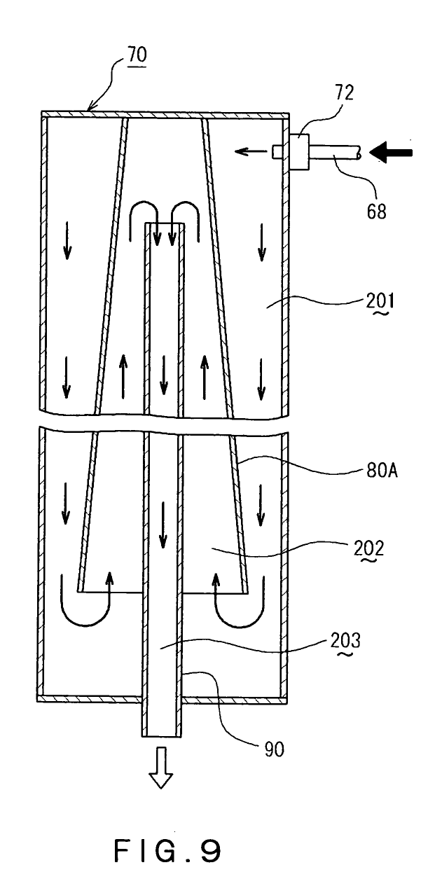

FIG. 9 is a schematic cross section showing a third embodiment according to the present invention.

The third embodiment is another example in which foreign matter such as a sublimate contained in an exhaust fluid can be removed more securely. As shown in FIG. 9, an intermediate pipe 80A is tapered to spread downwardly, and hence outer walls of the upstream guide passage 202 are formed to be tapered and spreading downwardly.

By providing such a configuration, since the flow speed of the exhaust fluid flowing in the upstream guide passage 202 can be decreased at a lower end portion of the intermediate exhaust pipe 80A, the settling by gravity of foreign matter in the exhaust fluid can be enhanced, thereby removing the foreign matter more securely.

It is also noted that since the other portions in the third embodiment other than described above are the same as those in the first embodiment, the description of such portions is omitted here.

### Other Embodiments

While the above embodiments have been described with respect to the case where a heating system comprising an exhaust system according to the present invention is applied to a heating system for use in a resist coating and developing system adapted for semiconductor wafers, it is should be understood that this invention can also be applied to a heating system for use in a resist coating and developing system adapted for LCD glass substrates.

1. An exhaust system for use in processing a substrate, which is connected to a processing chamber for containing the substrate to be processed, and adapted to discharge a fluid from the processing chamber, comprising:
an outer exhaust pipe connected to the processing chamber via an exhaust connecting pipe and having closed top and bottom ends;
a downstream guide passage formed in the outer exhaust pipe and adapted to downwardly guide an exhaust fluid flowing through the outer exhaust pipe;
an upstream guide passage formed in the outer exhaust pipe and adapted to upwardly guide the exhaust fluid having flowed through the downstream guide passage as well as to cause foreign matter or the like in the exhaust fluid to be settled by gravity; and
a discharging passage formed in the outer exhaust pipe and adapted to downwardly guide the exhaust fluid having flowed through the upstream guide passage to the outside, wherein a discharging means is provided in the discharging passage.

2. The exhaust system for use in processing a substrate according to claim 1, wherein
the downstream guide passage is formed between the outer exhaust pipe and an intermediate exhaust pipe which is connected to the top end of the outer exhaust pipe and has an opening bottom end; and wherein
the upstream guide passage is formed between the intermediate exhaust pipe and an inner exhaust pipe which is disposed in the intermediate exhaust pipe with a gap provided therebetween, has an opening top end, and extends through the bottom end of the outer exhaust pipe, and wherein the discharging passage is formed by the inner exhaust pipe.

3. The exhaust system for use in processing a substrate according to claim 2, wherein
a plurality of exhaust connecting pipes, each connected to a plurality of processing chambers are connected to the outer exhaust pipe.

4. The exhaust system for use in processing a substrate according to claim 2, wherein
a pressure detection means is provided in the outer exhaust pipe, for detecting pressure in the outer exhaust pipe so as to detect foreign matter or the like accumulated in the outer exhaust pipe.

5. The exhaust system for use in processing a substrate according to claim 2, wherein
a viewing window is provided near the bottom end of the outer exhaust pipe, for observing foreign matter accumulated in the outer exhaust pipe with eyes.

6. The exhaust system for use in processing a substrate according to claim 2, wherein
the intermediate exhaust pipe is tapered to spread downwardly.

7. The exhaust system for use in processing a substrate according to claim 2, wherein
among an inner wall face of the outer exhaust pipe, an inner wall face and an outer wall face of the intermediate exhaust pipe, and an outer wall face of the inner exhaust pipe, rough face portions for enhancing attachment of foreign matter in an exhaust fluid are formed at least in the inner wall face of the intermediate exhaust pipe and the outer wall face of the inner exhaust pipe.

8. The exhaust system for use in processing a substrate according to claim 2, wherein
the outer exhaust pipe is configured such that it can be divided into an upper half body to which the intermediate exhaust pipe is connected and a lower half body through which the inner exhaust pipe is inserted.

9. The exhaust system for use in processing a substrate according to claim 2, wherein
an antistatic process is provided to the exhaust connecting pipe.

10. The exhaust system for use in processing a substrate according to claim 1, wherein
a plurality of exhaust connecting pipes, each connected to a plurality of processing chambers are connected to the outer exhaust pipe.

11. The exhaust system for use in processing a substrate according to claim 1, wherein
a pressure detection means is provided in the outer exhaust pipe, for detecting pressure in the outer exhaust pipe so as to detect foreign matter or the like accumulated in the outer exhaust pipe.

12. The exhaust system for use in processing a substrate according to claim 1, wherein
a viewing window is provided near the bottom end of the outer exhaust pipe, for observing foreign matter accumulated in the outer exhaust pipe with eyes.

13. The exhaust system for use in processing a substrate according to claim 1, wherein
an antistatic process is provided to the exhaust connecting pipe.

14. The exhaust system for use in processing a substrate according to claim 1, wherein
the intermediate exhaust pipe is tapered to spread downwardly.
